(19) United States
(12) Patent Application Publication
(10) Pub. No.: US 2010/0025746 A1
(43) Pub. Date: Feb. 4, 2010

(54) METHODS, STRUCTURES AND SYSTEMS FOR INTERCONNECT STRUCTURES IN AN IMAGER SENSOR DEVICE

(75) Inventors: James Chapman, Boise, ID (US); Salman Akram, Boise, ID (US)

Correspondence Address: Treyz Law Group, 870 Market Street, Suite 984, San Francisco, CA, 94102, US

(73) Assignee: MICRON TECHNOLOGY, INC., Boise, ID (US)

(21) Appl. No.: 12/183,535

(22) Filed: Jul. 31, 2008

(51) Int. Cl. H01L 21/768; H01L 31/0224

(52) U.S. Cl. 257/292; 438/669; 257/E31.124; 257/E21.585

(57) ABSTRACT

Methods, structures and systems for a substantially non-light blocking conductive interconnect structure for an imager sensor device.

### TECHNICAL FIELD

In general, embodiments of the present invention relate to methods, structures, and systems for imager devices, and more specifically, to interconnect structures in imager sensor devices.

### BACKGROUND

In general, an imaging device, such as a Complimentary Metal Oxide Semiconductor (CMOS) imager sensor device includes a focal plane array of pixels, each one of the pixels includes a photo-conversion device, e.g., a photogate, photoconductor, or photodiode having an associated charge accumulation region within a substrate for accumulating photo-generated charge that can also include a capacitor to enhance charge storage. Each pixel can include a transfer transistor for transferring charge from the charge accumulation region to a diffusion node and a transistor for resetting the diffusion node to a predetermined charge level prior to charge transference. The pixel can also include a source follower transistor for receiving and amplifying charge from the diffusion node and an access transistor for controlling the readout of the pixel contents from the source follower transistor.

In a CMOS imager sensor device, each component of a pixel requires interconnection to form a pixel circuit comprising active elements that will perform various functions such as: (1) photon to charge conversion; (2) accumulation of image charge; (3) transfer of charge to the diffusion node accompanied by charge amplification (where a transfer transistor is used); (4) resetting the diffusion node to a known state before the transfer of charge to it; (5) selection of a pixel for readout; and (6) output and amplification of a reset signal and a signal representing pixel charge from the diffusion node. The charge at the floating diffusion node is typically converted to a pixel output voltage by the source follower output transistor.

Typically, the interconnection network of a CMOS imager sensor device includes various levels of metal lines that connect the active elements of each pixel to form a working pixel. Unfortunately, several problems can result from the use of metal interconnect structures. One such problem is that a metal local interconnect (an interconnection between active elements within each pixel circuit) can require additional processing steps in addition to those used to form the top plate of a capacitor. Another such problem is that the metal interconnect often requires special routing to ensure that metal does not block or limit electromagnetic radiation such as light from entering the photosensor.

It would be a distinct advantage to have an interconnect structure that avoids the previously described problems.

### BRIEF DESCRIPTION OF THE DRAWINGS

FIGS. 1A-1G are cross-sectional views of a semiconductor assembly comprising a segment of a CMOS imager sensor device during various stages of fabrication in accordance with a first embodiment.

FIGS. 2A-2E are cross-sectional views of a semiconductor assembly comprising a segment of a CMOS imager sensor device during various stages of fabrication in accordance with a second embodiment.

FIGS. 3A-3D are cross-sectional views of a semiconductor assembly comprising a segment of a CMOS imager sensor device during various stages of fabrication in accordance with a third embodiment.

FIG. 4 represents an example of a system that can use any one of the embodiments of FIGS. 1-3.

### DETAILED DESCRIPTION

The present invention is explained below in connection with various embodiments such as an electronic image capture device. These embodiments are solely for the purpose of providing a convenient and enabling discussion of the general applicability of the present invention, and are not intended to limit the various additional embodiments or applications to which the present invention can be applied as defined in the claims and their equivalents.

The terms “wafer” and “substrate” are to be understood as including silicon, silicon-on-insulator (SOI), or silicon-on-sapphire (SOS) technology, doped and undoped semiconductors, epitaxial layers of silicon supported by a base semiconductor foundation, and other semiconductor structures. Furthermore, when reference is made to a “wafer” or “substrate” in the following description, previous process steps may have been utilized to form regions or junctions in the base semiconductor structure or foundation. In addition, the semiconductor need not be silicon-based, but could be based on other semiconductors including silicon-germanium, germanium, or gallium-arsenide.

The term “pixel” includes but is not limited to a picture element unit cell containing a photosensor and transistors for converting electromagnetic radiation to an electrical signal.

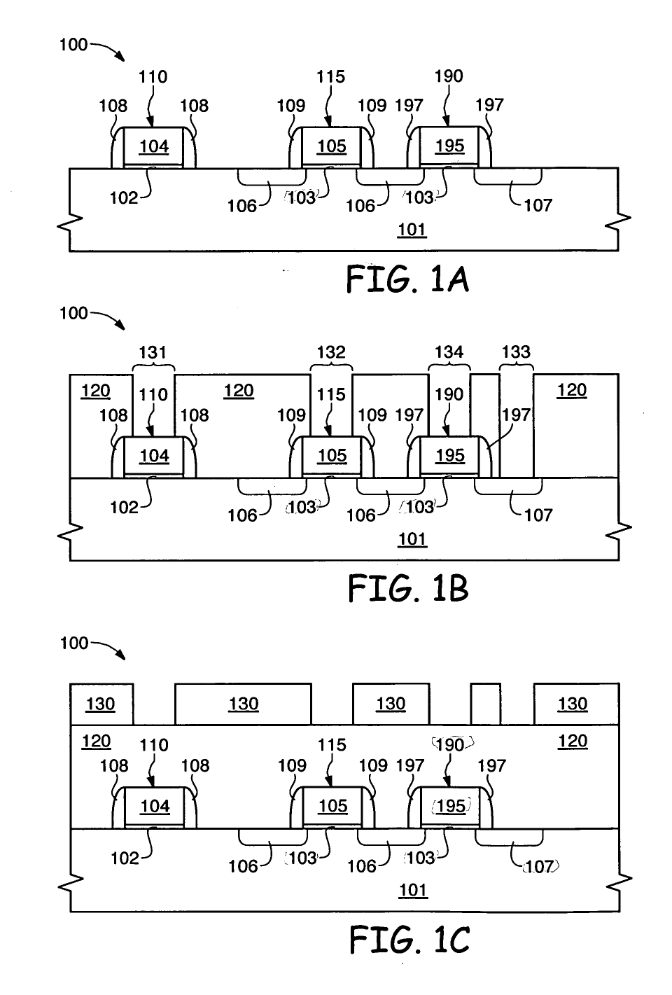

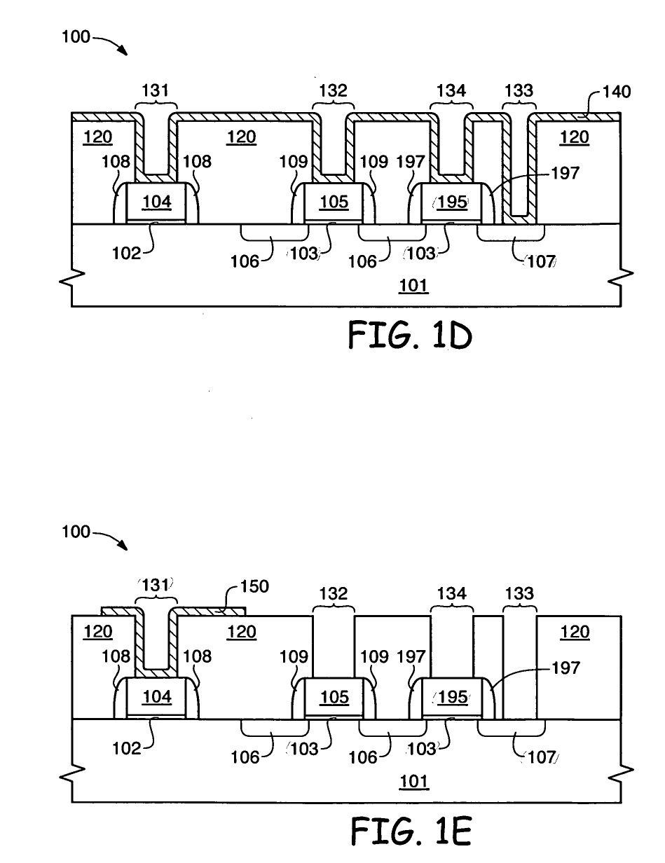

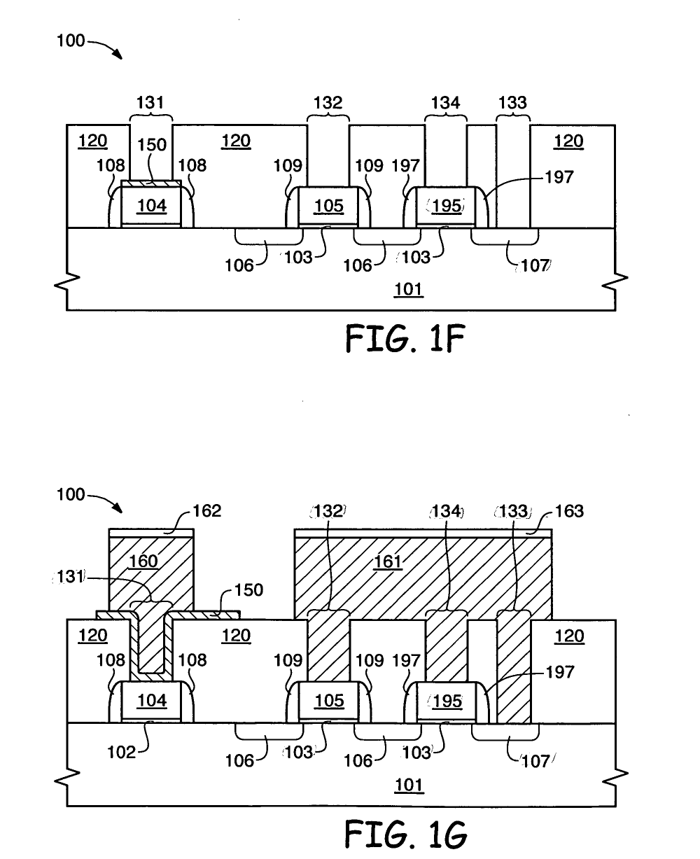

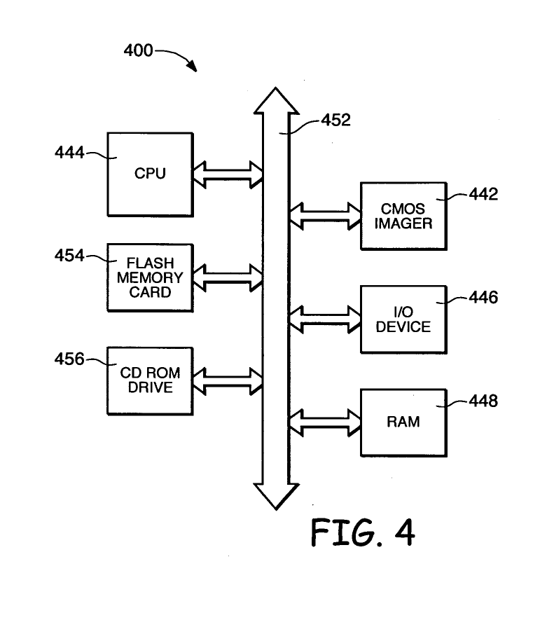

Embodiments of the present invention illustrate structures and methods to form local polysilicon interconnects in CMOS imager sensors, as described below with reference to FIGS. 1A-1G, FIGS. 2A-2E and FIGS. 3A-3E and each embodiment in conjunction with a general system application as illustrated in FIG. 4.

A cross-sectional view of a first embodiment of a CMOS imager sensor segment/cell 100 is shown in FIG. 1A. CMOS imager sensor segment 100 includes a p-type substrate section 101 on which an imager sensor pixel capacitor 110, a source follower transistor 115 and associated implants for an imager sensor cell, can be formed. A dielectric 102 can isolate an imager pixel capacitor bottom plate 104 that can be formed from a conductive material, such as conductively doped polysilicon, from semiconductor substrate section 101 (typically, a p-type substrate). Oxide dielectric 103 can serve as a gate dielectric to source follower transistor 115 and reset transistor 190, the gates 105 and 195 of which can also be formed from conductively doped polysilicon. Associated n-type conductive implants form diffusion regions 106 and 107. Diffusion regions 106 can function as source and drain electrodes for the source follower transistor 115 and reset transistor 190. The diffusion region implant 107 can function as a floating diffusion for the imager segment/cell 100.

Dielectric spacers 108, 109, and 197 can be formed along the capacitor bottom plate 104, source follower transistor gate 105, and reset transistor gate 195, respectively. Though not shown for simplicity sake, an insulation cap can reside on source follower transistor gate 105.

Referring now to FIG. 1B, an insulating material 120, such as borophosphosilicate glass (BPSG), can be formed over CMOS imager sensor segment 100 (by methods such as reflowing the BPSG) such that it covers the present structural components of pixel imager capacitor 110, source follower transistor 115, reset transistor 190, and the exposed portions of semiconductor substrate 101. Next, a material 130, such as photoresist, can be patterned to provide an etching pattern for subsequently formed contact openings to the capacitor bottom plate 104, source follower gate 105, reset gate 195, and the floating diffusion implant 107.

Referring now to FIG. 1C, an etch can be preformed using mask patterned material 130 (seen in FIG. 1C) to simultaneously form contact opening 131 to the capacitor bottom plate 104, contact opening 132 to source follower gate 105, contact opening 133 to floating diffusion implant 107, and contact opening 134 to reset gate 195. Any remaining mask patterned material 130 is then removed.

Referring now to FIG. 1D, a dielectric material 140 possessing a high dielectric constant (high-K) of at least 7 or greater, such as a nitride based dielectric material, can be formed over the insulating material 120, into contact openings 131, 132, 133, and 134 and on exposed capacitor bottom plate 104, exposed source follower gate 105, reset gate 195 and floating diffusion implant 107. If desired a wet oxide step may be performed prior to the formation of high-K dielectric material 140 in order to clean the capacitor bottom plate 104.

Referring now to FIG. 1E, high-K dielectric material 140 is patterned and etched to form a capacitor dielectric 150 such that it covers the previously exposed portion of capacitor bottom plate 104, remains along the patterned edges of contact opening 131 and extends along the patterned insulating material 120 to overlie at least the polysilicon material of the capacitor bottom plate 104. Also, during this etch, which can be either a wet etch or dry, the high-K dielectric material 140 is removed from contact openings 132, 133 and 134 to re-expose source follower transistor gate 105, reset gate 195, and floating diffusion implant 107.

FIG. 1F, represents an alternate method to form the capacitor dielectric 150 in that the capacitor dielectric 150 is formed and patterned prior to the formation of insulating layer 120, by processing techniques know to one skilled in the art.

Referring now to FIG. 1G, a non-light blocking conductive material such as a conductively doped polysilicon material can be formed over the capacitor dielectric 150, over insulating material 120 and into contact openings 132, 133 and 134. Next, polysilicon material is patterned and etched simultaneously to form a capacitor top plate 160 and a polysilicon local interconnect 161 which makes physical connection to source follower transistor gate 105, reset gate 195, and floating diffusion implant 107. Prior to patterning the polysilicon, an optional silicide material, such as titanium silicide (TiSi2) or cobalt silicide (CoSi2), can be formed on the polysilicon material so that once the polysilicon material is patterned, subsequent silicided capping layers 162 and 163 are formed on capacitor top plate 160 and polysilicon local interconnect 161.

The first embodiment has several advantages such as the polysilicon local interconnect is formed during the formation of the capacitor top plate. This avoids the additional mask steps that can be required during the formation of the local interconnect with metal.

Another advantage is that polysilicon can be routed over the photosensor of a pixel, such as a photodiode, since polysilicon does not substantially block light. In addition, the polysilicon can be silicided in areas where it would be desirable to block light, to provide an excellent conductive strap between transistors (thus lower resistance), and yet the added silicide does not require addition masking/processing steps. Further, the overall lower stack height of the resulting processed device may be shorter than one processed using metal local interconnecting lines.

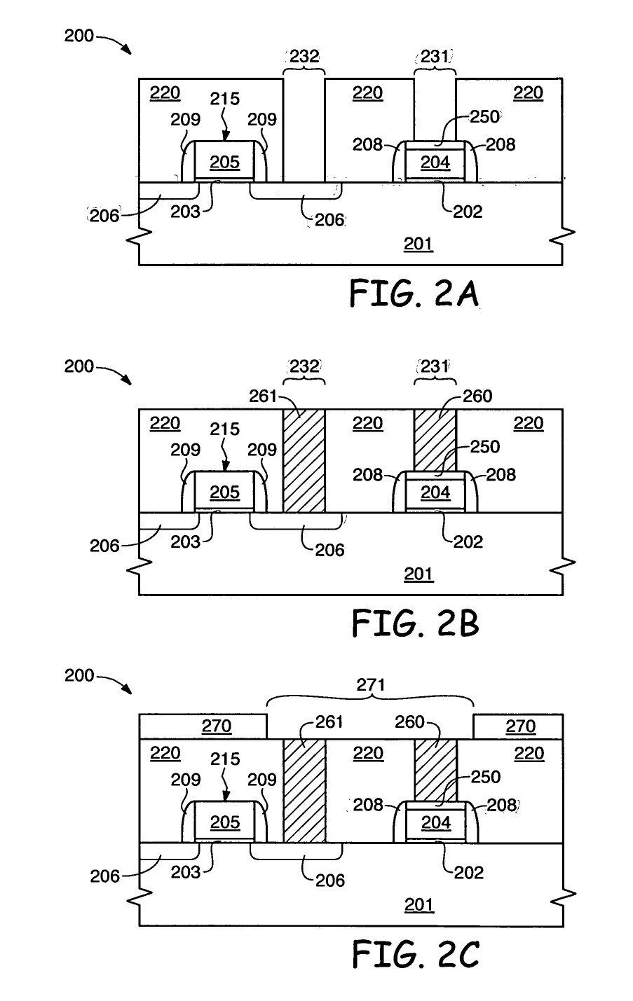

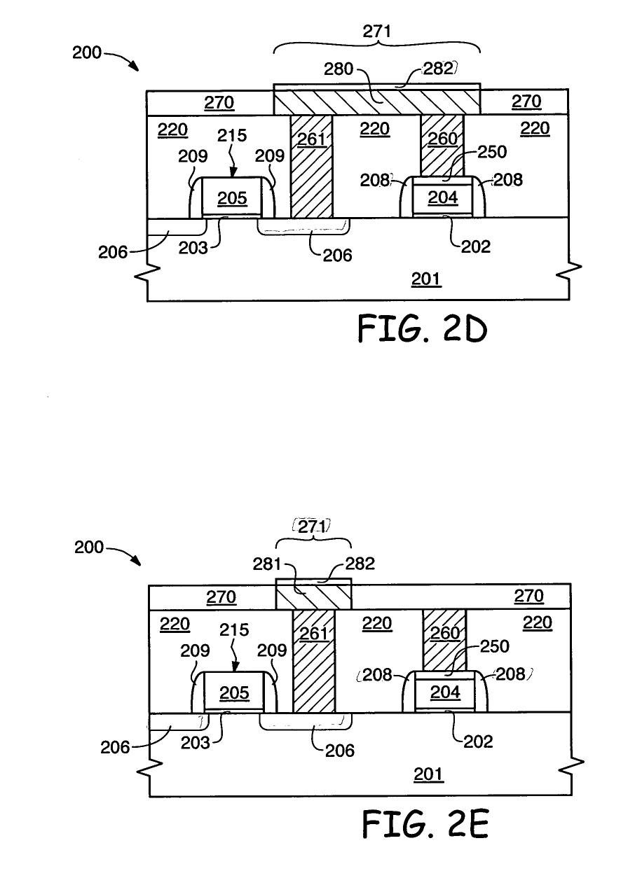

A second embodiment of the present invention is illustrated with a cross-sectional view of a CMOS imager sensor segment/cell 200 as shown in FIG. 2A. CMOS imager sensor segment 200 includes a p-type substrate section 201 on which an imager sensor pixel capacitor 210, a pixel transfer transistor 215 and associated implants for an imager sensor cell can be formed. A dielectric 202 isolates an imager pixel capacitor bottom plate 204, formed from a conductive material, such as a conductively doped polysilicon, from semiconductor substrate section 201 (typically, a p-type substrate). Oxide dielectric 203 serves as a gate dielectric to transfer transistor 215, the gate 205 of which can also formed from conductively doped polysilicon. Associated n-type conductive implants form diffusion regions 206 that serve as source and drain electrodes for the transfer transistor 215.

Dielectric spacers 208 are formed along the capacitor bottom plate 204 and dielectric spacers 209 are formed along transfer transistor gate 205. Though not shown for simplicity sake, an insulation cap can reside on transfer transistor gate 205.

Referring again to FIG. 2A, an insulating material 220, such as borophosphosilicate glass (BPSG), is formed over CMOS imager sensor segment 200 (e.g., reflowing the BPSG) such that it covers the present structural components of pixel imager capacitor 210, transfer transistor 215 and the exposed portions of semiconductor substrate 201. A dielectric material 250 possessing a high dielectric constant (high-K) of at least seven or greater, such as a nitride based dielectric material, is formed on exposed capacitor bottom plate 204 to create a capacitor cell dielectric. Next, an etch is preformed to simultaneously form contact opening 231 to the capacitor bottom plate 204 and contact opening 232 to transfer transistor source/drain region 206.

Referring now to FIG. 2B, a conductive material, preferably a conductively doped polysilicon material is formed to fill contact openings 231 and 232 and cover the upper surface of insulating material 220. The polysilicon material is then planarized, such as by chemical mechanical polishing, to simultaneously form a capacitor top plate 260 and a polysilicon local interconnect 261.

Referring now to FIG. 2C, a insulating material 270, such as silicon dioxide (SiO₂), is formed on the surface of insulating material 220 and planarized capacitor top plate 260 and planarized polysilicon interconnect 261. Insulating material 270 is patterned and etched to form trench 271 that re-exposes the surfaces capacitor top plate 260 and polysilicon interconnect 261.

Referring now to FIG. 2D, a non-light blocking conductive material, preferably a conductively doped polysilicon material, is formed on insulating material 270 and into trench 271, thus making contact to capacitor top plate 260 and polysilicon interconnect 261. The polysilicon material is then planarized to form a polysilicon interconnect 280 between capacitor top plate 260 and polysilicon interconnect 261. Prior to patterning the polysilicon, an optional silicide material, such as titanium silicide (TiSi2) or cobalt silicide (CoSi2), can be formed on the polysilicon material so that once the polysilicon material is patterned a subsequent silicided capping layer 282 is formed on polysilicon interconnect 280.

An alternative embodiment of FIG. 2D is illustrated in FIG. 2E where the insulating material 270 is patterned and etched to form trench 271 that re-exposes only the surface of polysilicon interconnect 261. Next, non-light blocking conductive material, preferably a conductively doped polysilicon is formed on insulating material 270 and into trench 271, thus making contact to polysilicon interconnect 261. The polysilicon material is then planarized to form a polysilicon interconnect 281 to polysilicon interconnect 261. Prior to patterning the polysilicon, an optional silicide material, such as titanium silicide (TiSi2) or cobalt silicide (CoSi2), may be formed on the polysilicon material so that once the polysilicon material is patterned, subsequent silicided capping layer 282 is formed on polysilicon interconnect 281.

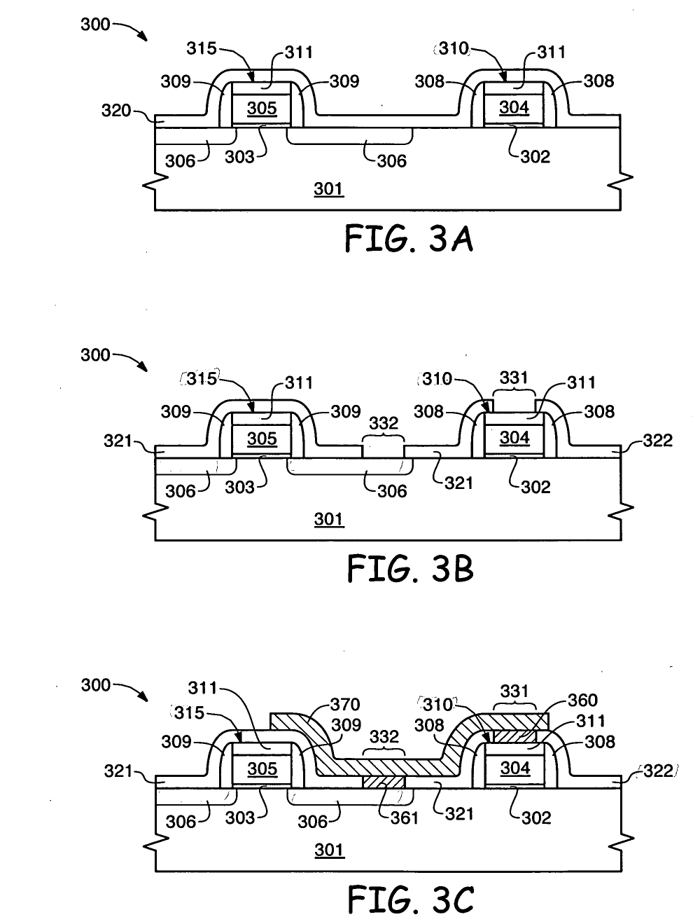

A third embodiment is illustrated by a cross-sectional view of a CMOS imager sensor segment 300 as shown in FIG. 3A. CMOS imager sensor segment 300 comprises a p-type substrate section 301 on which an imager sensor pixel capacitor 310, a pixel transfer transistor 315 and associated implants for an imager sensor cell. A dielectric 302 isolates an imager pixel capacitor bottom plate 304, formed from a conductive material, such as a conductively doped polysilicon material, from semiconductor substrate section 301 (typically, a p-type substrate). Oxide dielectric 303 serves as a gate dielectric to transfer transistor 315, the gate 305 of which may also formed from conductively doped polysilicon. Associated n-type conductive implants form diffusion regions 306 that serve as source and drain electrodes for the transfer transistor 315.

Dielectric spacers 308 are formed along the capacitor bottom plate 304 and dielectric spacers 309 are formed along transfer transistor gate 305. Though not shown for simplicity sake, an insulation cap can reside on transfer transistor gate 305.

Referring again to FIG. 3A, an insulating material 320, such as a conformal oxide material, is formed over CMOS imager sensor segment 300 such that it covers the present structural components of pixel imager capacitor 310, transfer transistor 315 and the exposed portions of semiconductor substrate 301.

Referring now to FIG. 3B, an etch is performed to simultaneously form contact opening 331 to the capacitor dielectric 311 and contact opening 332 to transfer transistor source/drain region 306, while forming further transfer transistor isolation 321 and capacitor isolation 322.

Referring now to FIG. 3C, non-light blocking conductive material, preferably a conductively doped polysilicon material, is formed to fill contact openings 331 and 332, cover the capacitor dielectric 311 and cover the upper surface of insulating material 320. The polysilicon material is then patterned to simultaneously form a capacitor top plate 360 and a polysilicon local interconnect 361, both of which are strapped together with polysilicon interconnect 370. Prior to patterning the polysilicon material, an optional silicide material, such as titanium silicide (TiSi2) or cobalt silicide (CoSi2), may be formed on the polysilicon material so that once the polysilicon material is patterned, a subsequent silicided capping layer 380 is formed on polysilicon local interconnect 370. Though, it is shown that the patterned polysilicon material forms separate structural components, it is to be understood that the separate structural components are formed from the same polysilicon layer.

The disclosed embodiments have several advantages such as forming the polysilicon local interconnect during the formation of the capacitor top plate. This avoids the additional mask steps that can be required during the formation of the local interconnect with metal. Another advantage is that polysilicon can be routed over the photosensor of a pixel, such as a photodiode, since polysilicon does not substantially block light. In addition, the polysilicon can be silicided in areas where it would be desirable to block light, to provide an excellent conductive strap between transistors (thus lower resistance), and yet the added silicide does not require addition masking/processing steps. Further, the overall lower stack height of the resulting processed device may be shorter than one processed using metal local interconnecting lines.

The previously described embodiments of the CMOS image sensors can be processed further as known in the art to fabricate a CMOS imager sensor device.

The illustration in FIG. 4 shows a typical processor system 400, which includes a CMOS imager 442 having an imaging sensor formed in any one of the embodiments described above. Processor system 400 is an example of a system having digital circuits, which could include the CMOS image sensor 442. The image sensor 442 provides an image signal produced from the pixels in the pixel array. Without being limiting, such a processor system could include a computer system, camera system, scanner, machine vision, vehicle navigation, video phone, surveillance system, auto focus system, star tracker system, motion detection system, image stabilization system and data compression system for high-definition television.

A processor system 400, such as a computer system, for example generally comprises a central processing unit (CPU) 444, for example, a microprocessor that communicates with an input/output (I/O) device 446 over a bus 452. The CMOS imager 442 also communicates with the system over bus 452. The computer system 400 may also include random access memory (RAM) 448, and in the case of a computer system may include peripheral devices such as a flash memory card 454, or a compact disk (CD) ROM drive 456 which also communicate with CPU 444 over the bus 452. It may also be desirable to integrate the processor 444, CMOS image sensor 442 and memory 448 on a single integrated circuit (IC) chip.

It should be noted that although the present invention has been described with specific reference to CMOS imager sensors, the present invention has broader applicability and can be used in any imaging apparatus. Similarly, the processes and interconnect structures described above are examples of many methods that could be used. The above description and drawings illustrate embodiments and are not intended to limit the present invention to the illustrated embodiments.

What is claimed is:

1. An imager sensor structure comprising:
a pixel cell source follower transistor having a gate;
a pixel cell capacitor having a plate formed from a conductive material that does not substantially block light;
a pixel cell floating diffusion;
an interconnect structure electrically connecting the source follower gate to the floating diffusion, the interconnect structure being formed from the conductive material at substantially the same time as the capacitor plate.

2. The imager sensor structure of claim 1, wherein the conductive material is conductively doped polysilicon.

3. The imager sensor structure of claim 2, wherein the surface of the conductively doped polysilicon comprises a silicide material.

4. The imager sensor structure of claim 3, wherein the silicide material comprises titanium silicide (TiSi2) or cobalt silicide (CoSi2).

5. The imager sensor structure of claim 1, wherein the imager sensor is a CMOS imager sensor device.

6. A method of forming an imager sensor interconnect structure comprising:
forming a first opening to a gate of a pixel cell source follower transistor;
forming a second opening to a pixel cell capacitor structure;
forming a third opening to a pixel cell floating diffusion;
forming a conductive material into the first, second and third openings, the conductive material substantially allowing light to pass through the conductive material;
patterning the conductive material to substantially simultaneously form a capacitor plate for the capacitor structure and an interconnect structure electrically connecting the source follower gate to the floating diffusion.

7. The method of forming the imager sensor interconnect structure of claim 6, wherein the conductive material is conductively doped polysilicon.

8. The method of forming the imager sensor interconnect structure of claim 7, wherein the surface of the conductively doped polysilicon is covered with a silicide material.

9. The method of forming the imager sensor interconnect structure of claim 8, wherein the silicide material comprises titanium silicide (TiSi2) or cobalt silicide (CoSi2).

10. An imager sensor structure comprising:
a pixel cell transfer transistor having a source/drain region;
a pixel cell capacitor structure;
a via connector of a substantially non-light blocking conductive material electrically connecting to the source/drain region; and
a cell capacitor structure having a plate formed from the substantially non-light blocking conductive material, the plate and via connector being formed from the same layer at substantially the same time.

11. The imager sensor structure of claim 10, wherein an interconnect structure of second substantially non light blocking conductive material electrically connecting the via connector of the source/drain region to the plate.

12. The imager sensor structure of claim 10, wherein an interconnect structure of a second substantially non-light blocking conductive material electrically connecting the via connector of the source/drain region but not connecting to the plate.

13. The imager sensor structure of claim 10, wherein the substantially non-light blocking conductive material is conductively doped polysilicon material.

14. The imager sensor structure of claim 11, wherein the second substantially non-light blocking conductive material is conductively doped polysilicon material.

15. The imager sensor structure of claim 12, wherein the second substantially non-light blocking conductive material is conductively doped polysilicon material.

16. The imager sensor structure of claim 13, wherein the surface of the conductively doped polysilicon material comprises a silicide material.

17. The imager sensor structure of claim 14, wherein the surface of the conductively doped polysilicon material comprises a silicide material.

18. The imager sensor structure of claim 15, wherein the silicide material comprises titanium silicide (TiSi2) or cobalt silicide (CoSi2).

19. The imager sensor structure of claim 16, wherein the silicide material comprises titanium silicide (TiSi2) or cobalt silicide (CoSi2).

20. The imager sensor structure of claim 10, wherein the imager sensor is a CMOS imager sensor device.

21. A method of forming an imager sensor interconnect structure comprising:
forming a first opening into a planarized insulating material to expose a source/drain region of a pixel cell transfer transistor;
forming a second opening into the planarized insulating material to expose to pixel cell capacitor structure, the first and second openings formed substantially simultaneously;
forming a substantially non-light blocking conductive material into the first and second openings;
patterning the substantially non-light blocking conductive material to substantially simultaneously form a capacitor plate for the capacitor structure and a via connector electrically connecting to the source/drain region.

22. The method of forming an imager sensor interconnect structure of claim 21, further comprising forming an interconnect structure of a second substantially non-light blocking conductive material to electrically connect the via connector to the plate.

23. The method of forming an imager sensor interconnect structure claim 21, further comprising forming an interconnect structure of a second substantially non-light blocking conductive material electrically connecting to the via connector but not connecting to the plate.

24. The method of forming an imager sensor interconnect structure of claim 21, wherein the substantially non-light blocking conductive material is conductively doped polysilicon.

25. The method of forming an imager sensor interconnect structure of claim 22, wherein the second substantially non-light blocking conductive material is conductively doped polysilicon material.

26. The method of forming an imager sensor interconnect structure of claim 23, wherein the second substantially non-light blocking conductive material is conductively doped polysilicon material.

27. The method of forming an imager sensor interconnect structure of claim 24, wherein a silicide material is formed on the surface of the conductively doped polysilicon material.

28. The method of forming an imager sensor interconnect structure of claim 25, wherein a silicide material is formed on the surface of the conductively doped polysilicon material.

29. The method of forming an imager sensor interconnect structure of claim 26, wherein the silicide material comprises titanium silicide (TiSi2) or cobalt silicide (CoSi2).

30. The method of forming an imager sensor interconnect structure claim 27, wherein the silicide material comprises titanium silicide (TiSi2) or cobalt silicide (CoSi2).

31. The method of forming an imager sensor interconnect structure of claim 21, wherein the imager sensor is a CMOS imager sensor device.

32. An imager sensor structure comprising:
a pixel cell transfer transistor having a source/drain region;
a pixel cell capacitor structure having a plate formed of substantially non-light blocking conductive material;
an insulating material conformal to the cell transfer transistor and the cell capacitor structure;
a via connector of a substantially non-light blocking conductive material electrically connecting to the source/drain region;
an interconnect structure of the substantially non-light blocking conductive material electrically connecting the via connector to the plate, the via connector, the capacitor plate and the interconnect structure being formed from the same layer of the substantially non-light blocking conductive material.

33. The imager sensor structure of claim 32, wherein the substantially non-light blocking conductive material is conductively doped polysilicon material.

34. The imager sensor structure of claim 33, wherein the surface of the conductively doped polysilicon material comprises a silicide material.

35. The imager sensor structure of claim 34, wherein the silicide material comprises titanium silicide (TiSi2) or cobalt silicide (CoSi2).

36. The imager sensor structure of claim 32, wherein the imager sensor is a CMOS imager sensor device.

37. A method of forming an imager sensor interconnect structure comprising:
forming a first opening into a conformal insulating material to expose a source/drain region of a pixel cell transfer transistor;
forming a second opening into the conformal insulating material to expose a pixel cell capacitor structure, the first and second openings formed substantially simultaneously;
forming a substantially non-light blocking conductive material into the first and second openings and on the conformal insulating material;
patterning the substantially non-light blocking conductive material to simultaneously form a capacitor plate for the capacitor structure, a via connector electrically connecting to the source/drain region and an interconnect structure electrically connecting between the capacitor plate and the via connector.

38. The method of forming an imager sensor interconnect structure of claim 37, wherein the substantially non-light blocking conductive material is conductively doped polysilicon.

39. The method of forming an imager sensor interconnect structure of claim 38, wherein a silicide material is formed on the surface of the conductively doped polysilicon material.

40. The method of forming an imager sensor interconnect structure of claim 39, wherein the silicide material comprises titanium silicide (TiSi2) or cobalt silicide (CoSi2).

41. The method of forming an imager sensor interconnect structure of claim 37, wherein the imager sensor is a CMOS imager sensor device.
